(19) United States
(12) Patent Application Publication
(10) Pub. No.: US 2010/0155942 A1
(43) Pub. Date: Jun. 24, 2010

(54) SEMICONDUCTOR DEVICE AND METHOD FOR FABRICATING THE SAME

(75) Inventors: Kouji TAKEMURA, Osaka (JP); Noriyuki Nagai, Nara (JP); Takatoshi Osumi, Nara (JP)

Correspondence Address: MCDERMOTT WILL & EMERY LLP, 600 13TH STREET, NW, WASHINGTON, DC, 20005-3096, US

(73) Assignee: Panasonic Corparation, Osaka (JP)

(21) Appl. No.: 12/713,799

(22) Filed: Feb. 26, 2010

Related U.S. Application Data
(63) Continuation of application No. PCT/JP2009/000638, filed on Feb. 17, 2009.

(30) Foreign Application Priority Data
Mar. 28, 2008 (JP) 2008-087099

(51) Int. Cl. H01L 23/498; H01L 21/768

(52) U.S. Cl. 257/737; 438/614; 257/E23.068; 257/E21.584

(57) ABSTRACT

A semiconductor device includes: a connection electrode formed on a side of a semiconductor element substrate opposed to a bump, where the semiconductor element substrate includes a semiconductor element; a passivation layer covering the semiconductor element substrate and an end portion of the connection electrode; and a barrier metal layer covering the connection electrode and a portion of the passivation layer so as to be electrically connected to the bump. A recess is formed in a portion of the passivation layer connected with the barrier metal layer.

### CROSS-REFERENCE TO RELATED APPLICATION

This is a continuation of PCT International Application PCT/JP2009/000638 filed on Feb. 17, 2009, which claims priority to Japanese Patent Application No. 2008-087099 filed on Mar. 28, 2008. The disclosures of these applications including the specifications, the drawings, and the claims are hereby incorporated by reference in its entirety.

### BACKGROUND

The present disclosure relates to semiconductor devices configured so that a mounting substrate is electrically connected to a semiconductor element through bumps, and methods for fabricating the same.

Conventionally, semiconductor devices have been widely used which are configured so that in order to mount a semiconductor element on a mounting substrate, bumps, such as solder bumps, are used to provide electrical connection therebetween. For example, a mounting substrate is made of glass fibers, and a semiconductor element substrate is made of silicon. Therefore, a mounting substrate and a semiconductor element substrate which are connected together through solder bumps have different coefficients of thermal expansion. For such a semiconductor device, there is a thermal expansion coefficient difference between a mounting substrate and a semiconductor element substrate. Therefore, heating and cooling of such a semiconductor device for bump connection cause expansion and shrinkage of the substrates. This causes problems, such as separation of a part of the semiconductor device in which substrates are connected together (hereinafter, referred to as “connection part”) from the bumps providing connection therebetween, and an instable electrical connection therebetween. It is significant to improve such problems arising from the thermal expansion coefficient difference.

FIG. 10 illustrates a known example of a semiconductor device configured so that a mounting substrate is electrically connected to a semiconductor element through solder bumps. FIG. 11 is an enlarged view of a portion of the semiconductor device illustrated in FIG. 10.

As illustrated in FIG. 10, a semiconductor device described in Japanese Patent Publication No. 2000-299343 is configured in the following manner: a semiconductor element 21 is formed on a semiconductor element substrate 22; and the semiconductor element 21 is connected, at the surface of the semiconductor element substrate 22 opposite to the surface thereof on which the semiconductor element 21 is formed, to a mounting substrate 24 through solder bumps 23.

Furthermore, as illustrated in FIG. 11, the semiconductor element substrate 22 includes a structure of a chip interconnect 25 and an insulating film 26, and a structure of a metal interconnect 27 and an insulating film 28 formed on the structure of the chip interconnect 25 and the insulating film 26. Openings are formed in the insulating film 28 forming a passivation film. The openings and their surrounding areas are covered with solder diffusion barrier layers 29 forming barrier metal layers. The metal interconnect 27 is connected to the solder bumps 23 through the openings. The stress caused in each of materials of the metal interconnect 27 and solder bump 23 due to the thermal expansion coefficient difference therebetween increases with an increase in the contact area between the materials. Therefore, as described in Japanese Patent Publication No. 2000-299343, openings are formed in a connection part of the semiconductor device to reduce the contact area between the metal interconnect 27 and each of the solder bumps 23, thereby reducing the stress. This stress reduction can stabilize the electrical connection between the metal interconnect 27 and the solder bump 23.

Moreover, although not illustrated, a semiconductor device described in Japanese Patent Publication No. S64-24434 is configured in the following manner: tongues are provided on a semiconductor element so that their heights allow the interval between a mounting substrate and the semiconductor element to become equal to a predetermined interval; and solder bumps are extended between the mounting substrate and the semiconductor element, thereby providing electrical connection therebetween. In this manner, even when shearing stress is applied to the solder bumps by thermal expansion of the mounting substrate and semiconductor element, shear strain and cracks are reduced, thereby providing a reliable semiconductor device.

### SUMMARY

However, for the semiconductor device described in Japanese Patent Publication No. 2000-299343, while cracks in the solder diffusion barrier layers 29, the metal interconnect 27, and the insulating films 26 and 28 which are all formed below the solder bumps 23 are prevented, the adhesion between the insulating film 28 and each solder diffusion barrier layer 29 is not taken into consideration. Since the bond strength between layers made of different materials is generally low, the bond strength between the insulating film 28 and the solder diffusion barrier layer 29 is low. Therefore, stress caused by expansion and shrinkage of the mounting substrate 24 and semiconductor element substrate 22 may cause separation between the insulating film 28 and the solder diffusion barrier layer 29. Furthermore, when minor separation occurs between the insulating film 28 and the solder diffusion barrier layer 29, in particular, from an end of the connection part, the stress may cause this minor separation to lead to significant separation and division therebetween from the area where the minor separation has occurred. This will cause unstable electrical connection between the metal interconnect 27 and the solder bumps 23. Moreover, formation of a plurality of openings reduces the contact area between the metal interconnect 27 and the solder diffusion barrier layer 29. This may reduce the amount of current flowing between the metal interconnect 27 and the solder diffusion barrier layer 29. Therefore, in reducing the sizes of semiconductor devices, a contact area large enough to ensure a sufficient amount of current cannot be ensured.

Furthermore, although, for the semiconductor device described in Japanese Patent Publication No. S64-24434, shear strain can be reduced, separation of a solder bump from a connection part of the semiconductor device cannot be prevented. Moreover, a process for providing the tongues is needed, and regions of the semiconductor element substrate on which the tongues are provided are also needed. Therefore, semiconductor devices cannot be miniaturized.

As described above, a known semiconductor device provides unstable electrical connection between a bump and a semiconductor element due to the thermal expansion coefficient difference therebetween. Furthermore, separation of the bump from a connection part of the semiconductor device cannot be prevented.

The present disclosure has been made in view of the aforementioned problems, and an object of the present disclosure is to prevent separation of a bump from a connection part of a semiconductor device due to the thermal expansion coefficient difference therebetween and stabilize the electrical connection between a bump and a semiconductor element.

In order to achieve the above object, a semiconductor device of the present disclosure is configured so that a portion of a passivation layer opposed to an end portion of a connection electrode has an uneven surface toward a mounting substrate. This prevents separation of the passivation layer from the end portion of the connection electrode, and stabilizes the electrical connection between a bump and a semiconductor element.

Specifically, a semiconductor device of the present disclosure is directed to a semiconductor device where a mounting substrate is electrically connected to a semiconductor element substrate including a semiconductor element through a bump. The device includes: the semiconductor element substrate on which a connection electrode connected with the semiconductor element is formed; a passivation layer covering the semiconductor element substrate and an end portion of the connection electrode; and a barrier metal layer covering the connection electrode and a portion of the passivation layer so as to be electrically connected to the bump. A first recess is formed in a portion of the passivation layer connected with the barrier metal layer.

According to the semiconductor device of the present disclosure, the formation of the first recess in the passivation layer increases the contact area between the passivation layer and the barrier metal layer, and brings an end portion of the portion of the passivation layer connected with the barrier metal layer into engagement with the barrier metal layer. This enables the mechanical connection between the passivation layer and the barrier metal layer to be solid. Such a solid connection can prevent separation between the passivation layer and the barrier metal layer. Furthermore, the amount of current between the bump and the semiconductor element can be prevented from being reduced.

In the semiconductor device of the present disclosure, the first recess is preferably formed in a portion of the passivation layer connected with the barrier metal layer and along an entire periphery of the portion of the passivation layer.

In the semiconductor device of the present disclosure, the first recess is preferably formed in a portion of the passivation layer connected with the barrier metal layer and along a part of a periphery of the portion of the passivation layer.

In the semiconductor device of the present disclosure, the first recess is preferably formed in a part of the passivation layer distant from a center of the semiconductor element substrate.

In the semiconductor device of the present disclosure, a second recess is preferably formed in a portion of the connection electrode connected with the passivation layer.

Thus, the formation of the second recess in the connection electrode increases the contact area between the connection electrode and the passivation layer, and brings an end portion of the portion of the connection electrode connected with the passivation layer into engagement with the passivation layer. This enables the mechanical connection between the connection electrode and the passivation layer to be solid. Such a solid connection can prevent separation between the connection electrode and the passivation layer. Furthermore, recesses can be formed in respective portions of the passivation layer, the barrier metal layer, and a bonding layer which are formed on the connection electrode formed with the second recess.

In the semiconductor device of the present disclosure, a cross section of the second recess is preferably V-shaped.

In the semiconductor device of the present disclosure, a sidewall of the second recess is preferably perpendicular to the semiconductor element substrate.

In the semiconductor device of the present disclosure, the second recess preferably passes through the connection electrode.

In the semiconductor device of the present disclosure, a third recess is preferably formed in an upper surface of a portion of the barrier metal layer connected with the passivation layer.

Thus, the formation of the third recess in the barrier metal layer increases the contact area between the barrier metal layer and the bonding layer, and brings an end portion of the portion of the barrier metal layer connected with the bonding layer into engagement with the bonding layer. This enables the mechanical connection between the barrier metal layer and the bonding layer to be solid. Such a solid connection can prevent separation between the barrier metal layer and the bonding layer.

In the semiconductor device of the present disclosure, a bonding layer is preferably formed on the barrier metal layer, and the bonding layer is preferably formed with a fourth recess.

Thus, the formation of the fourth recess in the bonding layer increases the contact area between the bonding layer and the bump, and brings an end portion of a portion of the bonding layer connected with the bump into engagement with the bump. This enables the mechanical connection between the bonding layer and the bump to be solid. Such a solid connection can prevent separation between the bonding layer and the bump.

In the semiconductor device of the present disclosure, a cross section of the first recess in the passivation layer is preferably V-shaped, and the barrier metal layer is preferably formed by plating.

Thus, better contact between the passivation layer and the barrier metal layer is provided. Therefore, no cavity is formed in the barrier metal layer.

A method for fabricating a semiconductor device of the present disclosure is directed to a method for fabricating a semiconductor device configured so that a mounting substrate is electrically connected to a semiconductor element substrate including a semiconductor element through a bump. The method includes: forming a connection electrode on a region of the semiconductor element substrate opposed to the bump; forming a recess in an end portion of the connection electrode; forming a passivation layer including an opening formed on a region of the semiconductor element substrate on which the connection electrode is formed except a region of the semiconductor element substrate on which a portion of the connection electrode formed with the recess is located; and after the forming the passivation layer, forming a barrier metal layer on the connection electrode.

In the method of the present disclosure, in the forming the recess, etching is preferably used.

In the method of the present disclosure, in the forming the barrier metal layer, plating is preferably used.

Thus, no cavity is formed in the barrier metal layer.

According to the semiconductor device of the present disclosure and the method for fabricating the same, separation between the connection electrode and the passivation layer can be prevented, and the electrical connection between the bump and the semiconductor element can be stabilized.

### BRIEF DESCRIPTION OF THE DRAWINGS

FIG. 1 is a schematic cross-sectional view illustrating a semiconductor device according to a first embodiment of the present disclosure.

FIG. 2 illustrates the semiconductor device according to the first embodiment of the present disclosure, and is an enlarged cross-sectional view of a portion of the semiconductor device in FIG. 1.

FIGS. 3A and 3B illustrate the semiconductor device according to the first embodiment of the present disclosure, and are enlarged cross-sectional views of a portion of the portion of the semiconductor device in FIG. 2.

FIGS. 4A and 4B are schematic plan views illustrating the semiconductor device according to the first embodiment of the present disclosure.

FIGS. 5A-5C are cross-sectional views illustrating process steps for fabricating the semiconductor device according to the first embodiment of the present disclosure.

FIGS. 6A-6C are cross-sectional views illustrating other process steps for fabricating the semiconductor device according to the first embodiment of the present disclosure.

FIG. 7 is an enlarged schematic cross-sectional view illustrating a portion of a semiconductor device according to a second embodiment of the present disclosure.

FIGS. 8A-8C are cross-sectional views illustrating process steps for fabricating the semiconductor device according to the second embodiment of the present disclosure.

FIGS. 9A and 9B are cross-sectional views illustrating other process steps for fabricating the semiconductor device according to the second embodiment of the present disclosure.

FIG. 10 is a schematic cross-sectional view illustrating a semiconductor device according to a known example.

FIG. 11 illustrates the semiconductor device according to the known example, and is an enlarged cross-sectional view of a portion of the semiconductor device in FIG. 10.

### DETAILED DESCRIPTION

### Embodiment 1

A first embodiment of the present disclosure will be described with reference to the drawings.

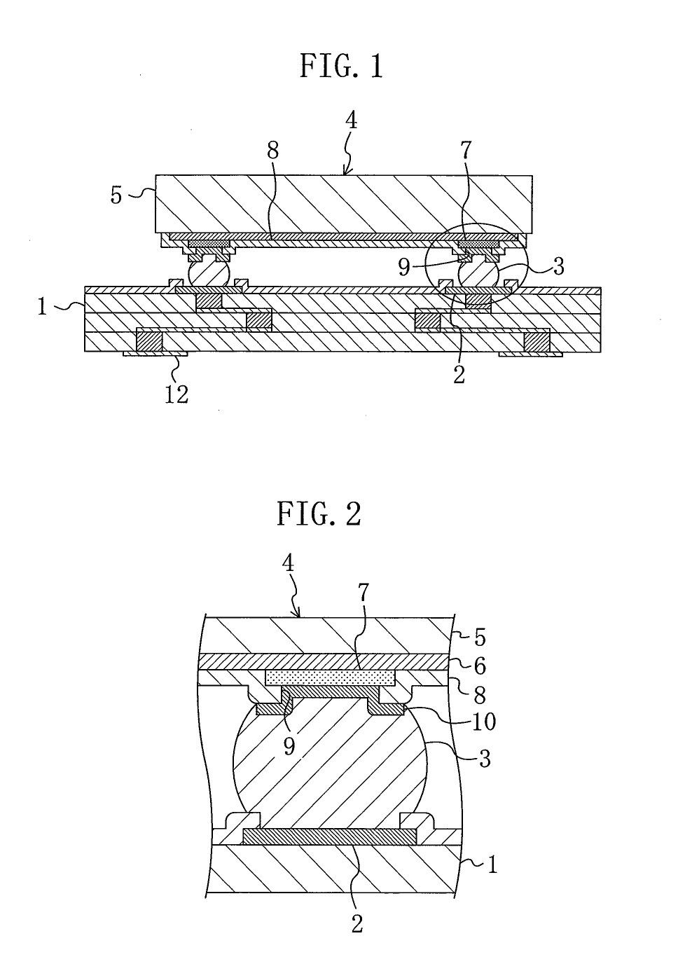

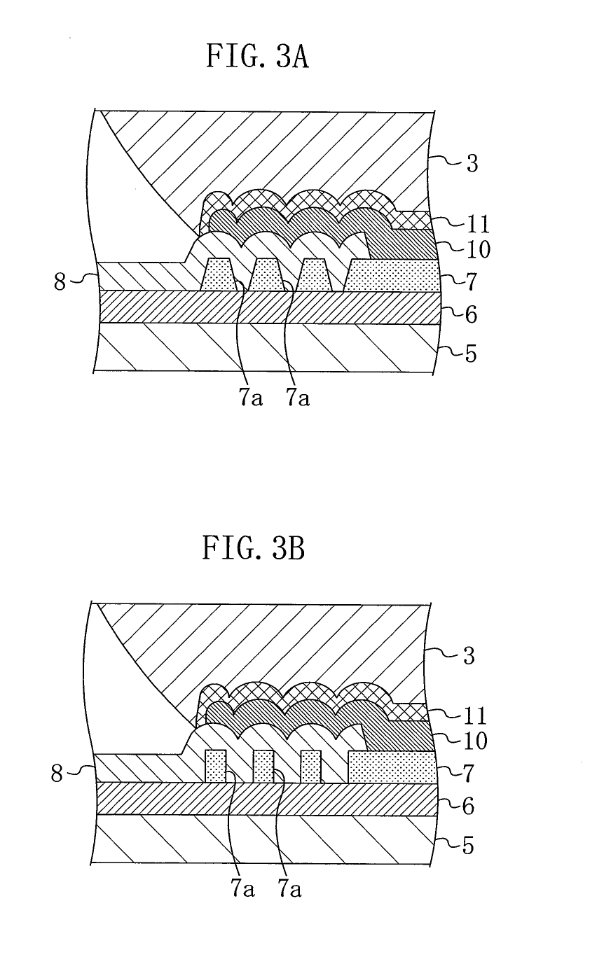

FIGS. 1-3B schematically illustrate a cross-sectional configuration of a semiconductor device according to the first embodiment of the present disclosure. FIG. 1 illustrates a cross-sectional configuration of the entire semiconductor device according to the first embodiment of the present disclosure. FIG. 2 illustrates a cross-sectional configuration of a portion of the semiconductor device in which a mounting substrate and a semiconductor element are connected together through a bump. FIGS. 3A and 3B are upside-down views of a portion of the portion of the semiconductor device in FIG. 2, and illustrate a cross-sectional configuration of a portion of the semiconductor device in which a semiconductor element substrate and a bump are connected together.

As illustrated in FIGS. 1 and 2, the semiconductor device according to the first embodiment of the present disclosure is configured so that a semiconductor element and a mounting substrate are electrically connected together through bumps. Connection terminals 2 provided on a mounting substrate 1 are electrically connected to a semiconductor element 4 through solder bumps 3. A semiconductor element substrate 5 is provided on the side of the semiconductor element 4 opposed to the mounting substrate 1. An insulating layer 6 made of, e.g., silicon nitride is formed on the semiconductor element substrate 5. Connection electrodes 7 made of e.g., aluminum (Al) are formed on regions of the insulating layer 6 opposed to the bumps 3. End portions of the connection electrodes 7 and a region of the insulating layer 6 on which the connection electrodes 7 are not formed are covered with a passivation layer 8 made of, e.g., silicon nitride. In other words, the passivation layer 8 is formed to have openings 9. The openings 9 are formed in portions of the passivation layer 8 located on the connection electrodes 7. Barrier metal layers 10 made of, e.g., nickel are formed to cover the openings 9 on the connection electrodes 7 and portions of the passivation layer 8 located around the openings 9. Furthermore, bonding layers 11 made of, e.g., gold are formed on the barrier metal layers 10. For the semiconductor device according to the present disclosure, mounting terminals 12 are provided on the lower surface of the mounting substrate 1. The semiconductor device is connected to a motherboard (not illustrated) of any one of various electronic devices by the mounting terminals 12.

As illustrated in FIGS. 3A and 3B, the passivation layer 8 and the barrier metal layers 10 are in contact with the entire surfaces of the connection electrodes 7. A plurality of recesses 7a are formed in an end portion of each of the connection electrodes 7, i.e., a portion of the connection electrode 7 connected with the passivation layer 8, to reach the insulating layer 6. The recesses 7a may be V-shaped as illustrated in FIG. 3A. Alternatively, the recesses 7a may have a sidewall perpendicular to the semiconductor element substrate 5 as illustrated in FIG. 3B. Since the plurality of recesses 7a are formed in the connection electrode 7, the connection electrode 7 has an uneven surface. Therefore, the portion of the connection electrode 7 connected with the passivation layer 8 is brought into engagement with the passivation layer 8. This enables the mechanical connection between the connection electrode 7 and the passivation layer 8 to be solid.

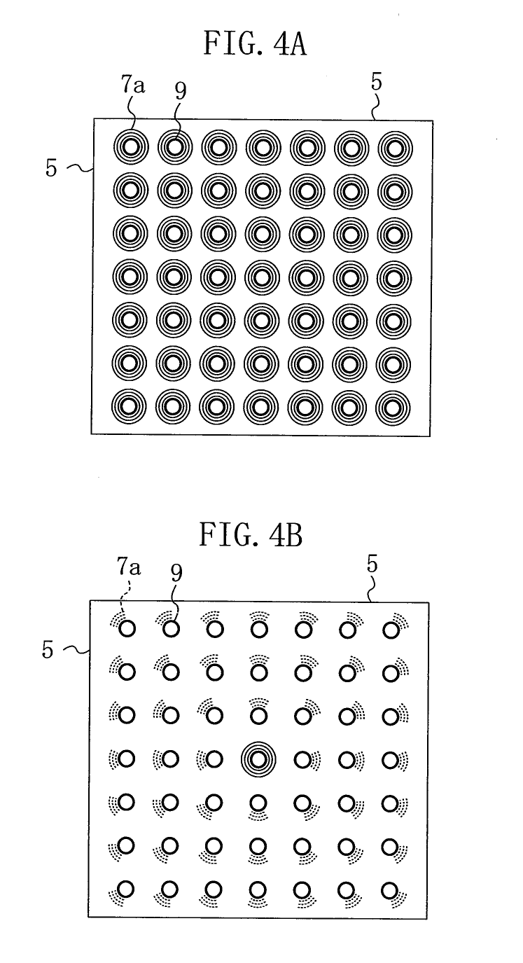

FIGS. 4A and 4B are plan views illustrating the positional relationship between the openings 9 in the passivation layer 8 and the recesses 7a relative to the semiconductor element substrate 5.

As illustrated in FIG. 4A, the recesses 7a are formed around the openings 9 in the passivation layer 8 provided on the semiconductor element substrate 5. They are formed around the openings 9 in a plurality of rows. Although not illustrated, they may be formed in a random fashion without being formed in a plurality of rows.

Alternatively, as illustrated in FIG. 4B, the recesses 7a may be formed in a region surrounding each opening 9 and being radially distant from the center of the semiconductor element substrate 5. The highest stresses caused by the thermal expansion coefficient difference are applied to parts of the corresponding semiconductor element located immediately outside the openings 9 and distant from the center of the semiconductor element. For this reason, when the recesses 7a are formed in the parts of the semiconductor element to which the highest stresses are applied, this can prevent separation caused by the stresses. In view of the above, when the recesses 7a are formed at locations where separation tends to be caused by stresses, at least along parts of the peripheries of the openings 9 radially distant from the center of the semiconductor element 4, this can prevent the separation. Also when recesses 7a are formed at locations corresponding to corner portions of the semiconductor element substrate 5, the same advantages can be provided. Furthermore, the formation of the recesses 7a as described above can improve process stability.

In FIGS. 4A and 4B, the openings 9 are circular. However, they may be polygonal, and are not limited to circular ones.

When the recesses 7a are formed in the end portion of each connection electrode 7 as described above, recesses are formed also in layers above the connection electrode 7 formed with the recesses 7a. Specifically, recesses are formed in the passivation layer 8 in correspondence with the recesses 7a; recesses are formed in the corresponding barrier metal layer 10 in correspondence with the recesses formed in the passivation layer 8; and recesses are formed in the corresponding bonding layer 11 in correspondence with the recesses formed in the corresponding barrier metal layer 10. Therefore, the corresponding bump 3 is formed to enter the recesses in the corresponding bonding layer 11. This increases the contact areas between the connection electrode 7 and the passivation layer 8, between the passivation layer 8 and the corresponding barrier metal layer 10, between the corresponding barrier metal layer 10 and the corresponding bonding layer 11, and between the corresponding bonding layer 11 and the corresponding bump 3, and brings the connection electrode 7, the passivation layer 8, the corresponding barrier metal layer 10, and the corresponding bonding layer 11 into engagement with the passivation layer 8, the corresponding barrier metal layer 10, the corresponding bonding layer 11, and the corresponding bump 3, respectively, at the contact interfaces. This enables the mechanical connections between the connection electrode 7 and the passivation layer 8, between the passivation layer 8 and the corresponding barrier metal layer 10, between the corresponding barrier metal layer 10 and the corresponding bonding layer 11, and between the corresponding bonding layer 11 and the corresponding bump 3 to be solid.

Here, while the connection electrodes 7, the barrier metal layers 10, the bonding layers 11, and the bumps 3 are made of a metal material, the passivation layer 8 is made of an insulating film of, e.g., silicon nitride. In other words, a material of the passivation layer 8 is different from materials of the other above-mentioned components. Therefore, the bond strengths between the passivation layer 8 and the barrier metal layers 10 are low. For this reason, stresses arising from expansion and shrinkage of the mounting substrate 1 and semiconductor element substrate 5 may cause separation between the passivation layer 8 and the barrier metal layers 10, thereby leading to unstable electrical connections therebetween. However, according to the semiconductor device of the present disclosure, the contact area between the passivation layer 8 and each barrier metal layer 10 is increased by the recesses formed in the passivation layer 8, and the passivation layer 8 is brought into engagement with the barrier metal layer 10. This enables the mechanical connection between the passivation layer 8 and the barrier metal layer 10 to be solid. Such a solid connection can prevent separation between the passivation layer 8 and the barrier metal layer 10. This prevention can stabilize the electrical connections between the bumps 3 and the semiconductor element 4.

Furthermore, according to the semiconductor device of the present disclosure, also for the connection between each bonding layer 11 and the corresponding bump 3, the contact area therebetween is increased by the recesses formed in the bonding layer 11, and the bonding layer 11 is brought into engagement with the corresponding bump 3. This enables the mechanical connection between the bonding layer 11 and the corresponding bump 3 to be solid, and can reduce the electrical resistance therebetween.

As described above, according to the semiconductor device of the first embodiment of the present disclosure, the recesses 7a are formed in the end portions of the connection electrodes 7 provided on the semiconductor element substrate 5, thereby forming recesses also in the passivation layer 8, the barrier metal layers 10, and the bonding layers 11 all covering the recesses 7a. This can increase the contact areas between these layers and layers located immediately above these layers, and thus these layers are brought into engagement with the layers located immediately above them. This enables the mechanical connections between these layers and the layers located immediately above these layers to be solid. Therefore, the connections between the passivation layer 8 and the barrier metal layers 10 made of a material different from that of the passivation layer 8 also become solid. This can prevent separation between the passivation layer 8 and the barrier metal layers 10 from being caused by stresses. This prevention can stabilize the electrical connections between the passivation layer 8 and the barrier metal layers 10. Furthermore, when the recesses 7a are formed only in the end portions of the connection electrodes 7, this can sufficiently prevent the separation, and can prevent the amount of currents flowing between the bumps 3 and the semiconductor element 4 from being reduced.

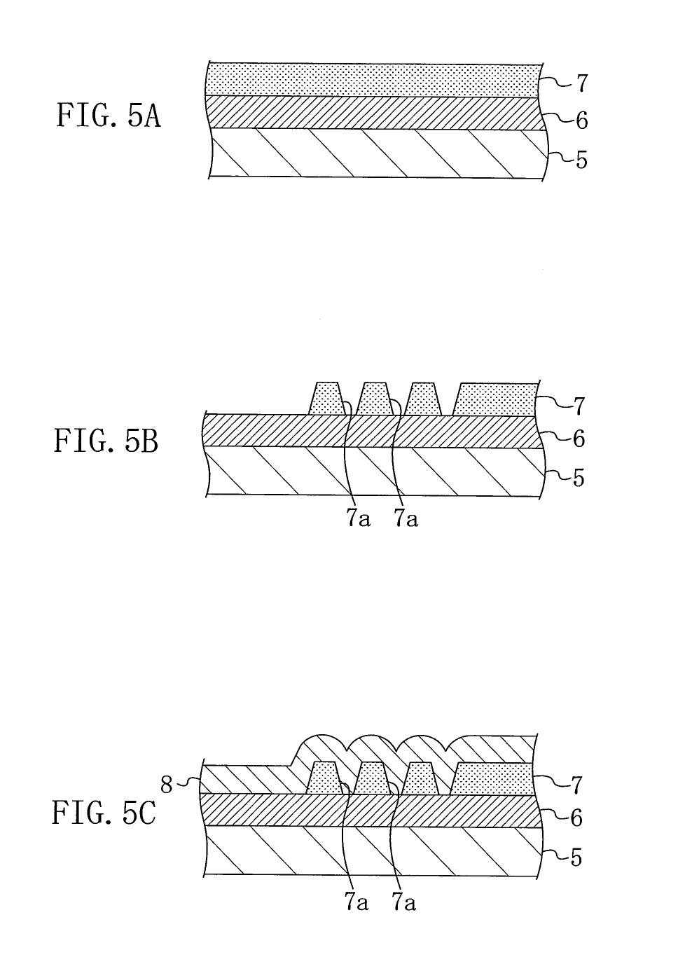

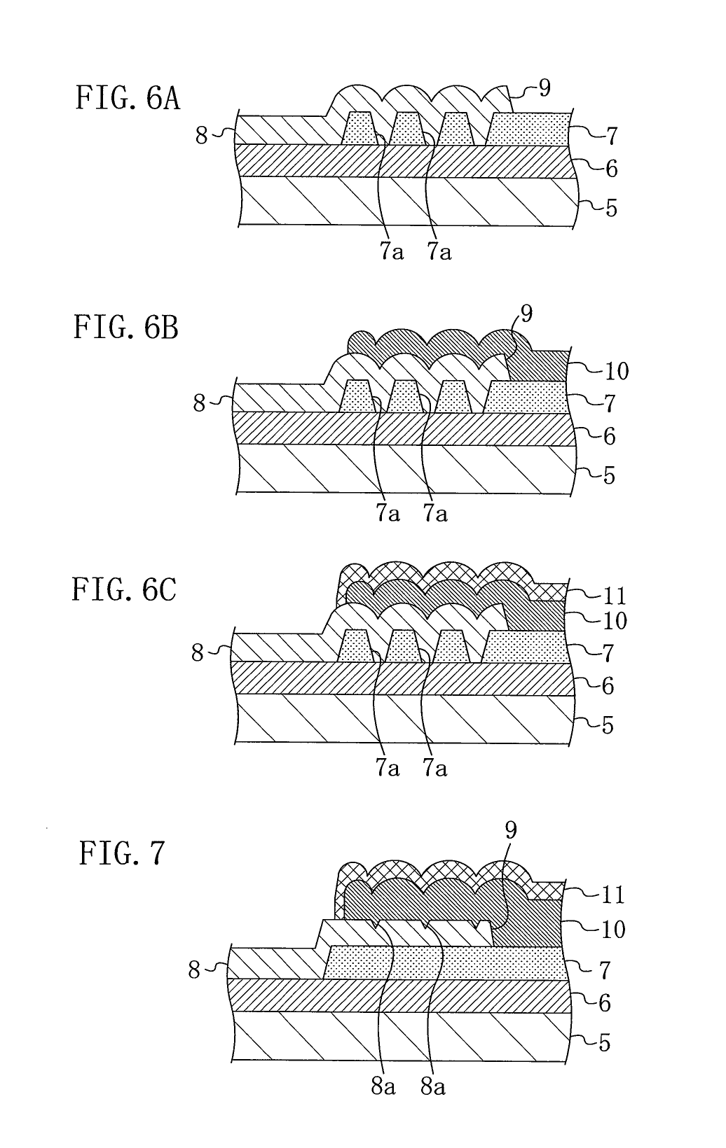

A method for fabricating a semiconductor device according to the first embodiment of the present disclosure will be described hereinafter with reference to FIGS. 5A-6C.

FIGS. 5A-6C illustrate the semiconductor device according to the first embodiment of the present disclosure in process steps for fabricating the semiconductor device in a sequential order, and are cross-sectional views illustrating the process steps and corresponding to the cross-sectional view in FIG. 3A.

As illustrated in FIG. 5A, a semiconductor element 4 is formed with a semiconductor element substrate 5. An insulating layer 6 made of, e.g., silicon nitride, and a connection electrode formation film which will partially form a connection electrode 7 and is made of, e.g., aluminum (Al) are sequentially formed on the side of the semiconductor element substrate 5 opposed to a mounting substrate 1.

Next, as illustrated in FIG. 5B, the connection electrode formation film is subjected to dry or wet etching, thereby forming a connection electrode 7 having an end portion formed with recesses 7a. In this case, the recesses 7a are deep enough to reach the insulating layer 6, and their cross sections are V-shaped.

Next, as illustrated in FIG. 5C, a passivation layer 8 is formed to cover a portion of the insulating layer 6 on which the connection electrode 7 is not formed, and the connection electrode 7 including the recesses 7a. Here, since the recesses 7a are formed in the end portion of the connection electrode 7, portions of the passivation layer 8 covering the recesses 7a enter the recesses 7a. Therefore, V-shaped recesses are formed also in the passivation layer 8 in correspondence with the recesses 7a in the connection electrode 7.

Next, as illustrated in FIG. 6A, a portion of the passivation layer 8 located on the connection electrode 7 is removed by dry or wet etching, thereby forming an opening 9 for connection.

Next, as illustrated in FIG. 6B, a barrier metal layer 10 is formed by plating to cover the opening 9 and its surrounding area. Here, the barrier metal layer 10 also covers the V-shaped recesses formed in the passivation layer 8. The barrier metal layer 10 is smoothly grown from the opening 9 toward its surrounding area. As such, since the barrier metal layer 10 is smoothly grown away from the opening 9 to also cover the V-shaped recesses formed in the passivation layer 8, V-shaped recesses are formed also in the barrier metal layer 10 in correspondence with the recesses formed in the passivation layer 8. In view of the above, no cavity is formed in a portion of the barrier metal layer 10 covering a portion of the passivation layer 8. This enables the connection between the passivation layer 8 and the barrier metal layer 10 to be solid.

Next, as illustrated in FIG. 6C, a bonding layer 11 is formed on the surface of the barrier metal layer 10 by plating.

Thus, although not illustrated, the formed semiconductor device is mounted on a motherboard (not illustrated) of any one of various electronic devices by mounting terminals 12 provided on the lower surface of the mounting substrate 1.

In the first embodiment of the present disclosure, the bonding layers 11 are provided between the barrier metal layers 10 and the bumps 3. However, the bonding layers 11 do not need to be formed. Also when the bonding layers 11 are not formed, the same advantages can be provided.

### Embodiment 2

A second embodiment of the present disclosure will be described hereinafter with reference to the drawings.

FIG. 7 illustrates a cross-sectional structure of a semiconductor device according to the second embodiment of the present disclosure, and illustrates a cross-sectional structure of a portion of a semiconductor element substrate connected to a bump. The cross-sectional structure in FIG. 7 corresponds to that in FIG. 3A or 3B in the first embodiment of the present disclosure. In the second embodiment, the same reference characters as those in the first embodiment are used to represent equivalent elements, and the explanation thereof will be omitted. The second embodiment is similar to the first embodiment except that no recess 7a is formed in a connection electrode 7.

As illustrated in FIG. 7, the semiconductor device according to the second embodiment of the present disclosure is configured so that recesses 8a are formed in a passivation layer 8 without forming recesses 7a in a connection electrode 7. When the recesses 8a are formed in a portion of the passivation layer 8 located on the connection electrode 7, this increases the contact area between the passivation layer 8 and a barrier metal layer 10, and brings the passivation layer 8 into engagement with the barrier metal layer 10. This enables the mechanical connection between the passivation layer 8 and the barrier metal layer 10 to be solid. Such a solid connection can prevent separation between the passivation layer 8 and the barrier metal layer 10, thereby stabilizing the electrical connection therebetween.

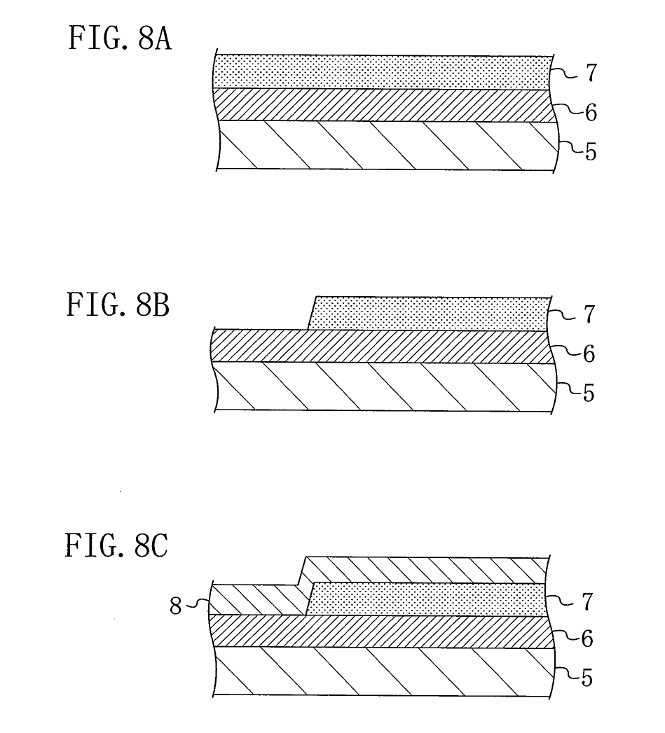

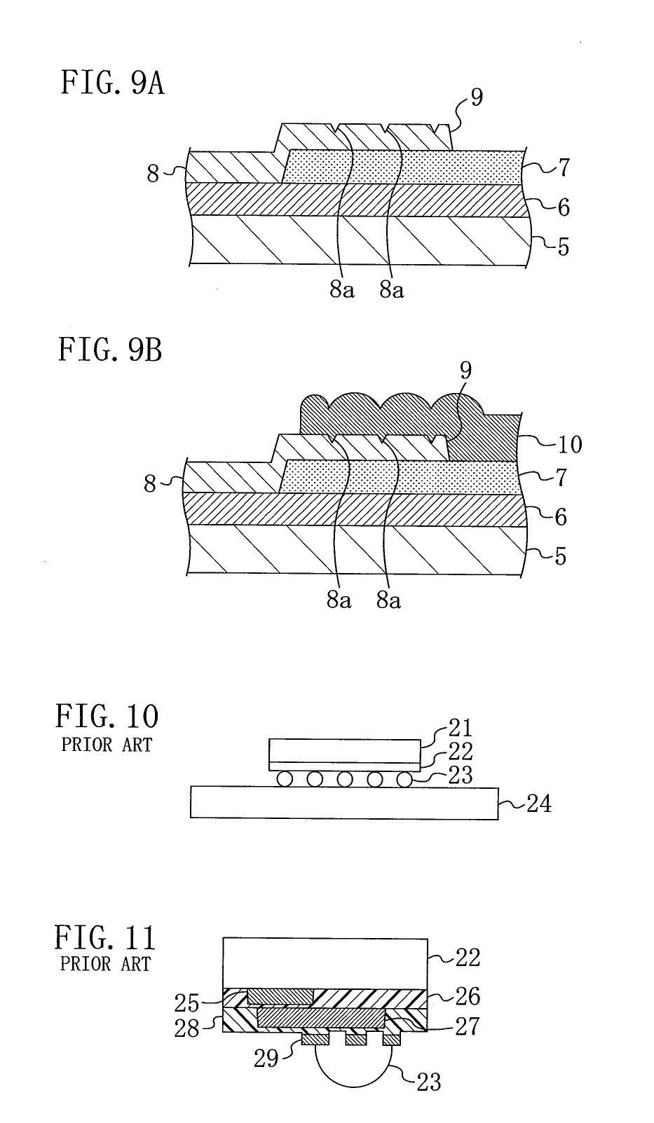

A method for fabricating a semiconductor device according to a second embodiment of the present disclosure will be described hereinafter with reference to FIGS. 8A-9B.

FIGS. 8A-9B illustrate the semiconductor device according to the second embodiment of the present disclosure in process steps for fabricating the semiconductor device in a sequential order, and are cross-sectional views illustrating the process steps and corresponding to the cross-sectional view in FIG. 7.

As illustrated in FIG. 8A, a semiconductor element 4 is formed with a semiconductor element substrate 5. An insulating layer 6 made of, e.g., silicon nitride and a connection electrode formation film which will partially form a connection electrode 7 and is made of, e.g., aluminum (Al) are sequentially formed on the side of the semiconductor element substrate 5 opposed to a mounting substrate 1.

Next, as illustrated in FIG. 8B, the connection electrode formation film is subjected to dry or wet etching, thereby forming a connection electrode 7.

Next, as illustrated in FIG. 8C, a passivation layer 8 is formed to cover a portion of the insulating layer 6 on which the connection electrode 7 is not formed, and the connection electrode 7.

Next, as illustrated in FIG. 9A, dry or wet etching allows recesses 8a to be formed in a portion of the passivation layer 8 located on an end portion of the connection electrode 7, and allows an opening 9 for connection to be formed in a portion of the passivation layer 8 located on the connection electrode 7. The recesses 8a formed in the passivation layer 8 do not reach the connection electrode 7, and their cross sections are V-shaped. The recesses 8a and the opening 9 may be formed in the same process step using the same mask by adjusting openings in a resist. Alternatively, they may be formed in different process steps using different masks.

Next, as illustrated in FIG. 9B, a barrier metal layer 10 is formed by plating to cover the opening 9 and its surrounding area. Here, the barrier metal layer 10 also covers the V-shaped recesses formed in the passivation layer 8. The barrier metal layer 10 is smoothly grown from the opening 9 toward its surrounding area. As such, since the barrier metal layer 10 is smoothly grown away from the opening 9 to also cover the V-shaped recesses formed in the passivation layer 8, V-shaped recesses are formed also in the barrier metal layer 10 in correspondence with the recesses formed in the passivation layer 8. In view of the above, no cavity is formed in a portion of the barrier metal layer 10 covering a portion of the passivation layer 8. This enables the connection between the passivation layer 8 and the barrier metal layer 10 to be solid.

A method for forming the recesses 8a is not limited to dry or wet etching. The recesses 8a may be formed by other methods.

The semiconductor device of the present disclosure and the method for fabricating the same can prevent separation between a connection electrode and a passivation layer, and can stabilize the electrical connection between a bump and a semiconductor element. They are useful for semiconductor devices configured so that a mounting substrate is electrically connected to a semiconductor element through bumps, and methods for fabricating the same.

What is claimed is:

1. A semiconductor device where a mounting substrate is electrically connected to a semiconductor element substrate including a semiconductor element through a bump, the device comprising:
the semiconductor element substrate on which a connection electrode connected with the semiconductor element is formed;
a passivation layer covering the semiconductor element substrate and an end portion of the connection electrode; and
a barrier metal layer covering the connection electrode and a portion of the passivation layer so as to be electrically connected to the bump,
wherein a first recess is formed in a portion of the passivation layer connected with the barrier metal layer.

2. The semiconductor device of claim 1, wherein
the first recess is formed in a portion of the passivation layer connected with the barrier metal layer and along an entire periphery of the portion of the passivation layer.

3. The semiconductor device of claim 1, wherein
the first recess is formed in a portion of the passivation layer connected with the barrier metal layer and along a part of a periphery of the portion of the passivation layer.

4. The semiconductor device of claim 3, wherein
the first recess is formed in a part of the passivation layer distant from a center of the semiconductor element substrate.

5. The semiconductor device of claim 1, wherein
a second recess is formed in a portion of the connection electrode connected with the passivation layer.

6. The semiconductor device of claim 5, wherein
a cross section of the second recess is V-shaped.

7. The semiconductor device of claim 5, wherein
a sidewall of the second recess is perpendicular to the semiconductor element substrate.

8. The semiconductor device of claim 5, wherein
the second recess passes through the connection electrode.

9. The semiconductor device of claim 1, wherein
a third recess is formed in an upper surface of a portion of the barrier metal layer connected with the passivation layer.

10. The semiconductor device of claim 1, wherein
a bonding layer is formed on the barrier metal layer, and
the bonding layer is formed with a fourth recess.

11. The semiconductor device of claim 1, wherein
a cross section of the first recess in the passivation layer is V-shaped, and
the barrier metal layer is formed by plating.

12. A method for fabricating a semiconductor device configured so that a mounting substrate is electrically connected to a semiconductor element substrate including a semiconductor element through a bump, the method comprising:
forming a connection electrode on a region of the semiconductor element substrate opposed to the bump;
forming a recess in an end portion of the connection electrode;
forming a passivation layer including an opening formed on a region of the semiconductor element substrate on which the connection electrode is formed except a region of the semiconductor element substrate on which a portion of the connection electrode formed with the recess is located; and
after the forming the passivation layer, forming a barrier metal layer on the connection electrode.

13. The method of claim 12, wherein
in the forming the recess, etching is used.

14. The method of claim 12, wherein
in the forming the barrier metal layer, plating is used.
